(19) United States
(12) Patent Application Publication
(10) Pub. No.: US 2026/0032839 A1
(43) Pub. Date: Jan. 29, 2026

(54) SEMICONDUCTOR DEVICE INCLUDING MULTI-PURPOSE TRANSCEIVER AND AN OPERATION METHOD THEREOF

(71) Applicant: SK hynix Inc., Gyeonggi-do (KR)

(72) Inventors: Jae Hyeong HONG, Gyeonggi-do (KR); Gwan Woo KIM, Gyeonggi-do (KR); Heon Ki KIM, Gyeonggi-do (KR); Beom Kyu SEO, Gyeonggi-do (KR); Keun Seon AHN, Gyeonggi-do (KR); Soon Sung AN, Gyeonggi-do (KR); Sung Hwa OK, Gyeonggi-do (KR); Ji Young LEE, Gyeonggi-do (KR); Jun Seo JANG, Gyeonggi-do (KR); Eun Ji CHOI, Gyeonggi-do (KR)

(21) Appl. No.: 18/957,872

(22) Filed: Nov. 25, 2024

(30) Foreign Application Priority Data
Jul. 23, 2024 (KR) 10-2024-0097045

(51) Int. Cl. H05K 5/02

(52) U.S. Cl. CPC H05K 5/0247

(57) ABSTRACT

A semiconductor device includes plural electrical terminals or pads, and plural transceivers configured to transmit or receive power, data, or control signals through the plural electrical terminals or pads and including a first transceiver. The first transceiver is configured to perform an operation based on an operation mode by using either a pair of electrical terminals or pads or a single electrical terminal or pad among the pair of electrical terminals or pads.

### CROSS-REFERENCE TO RELATED APPLICATIONS

This patent application claims the benefit of priority under 35 U.S.C. § 119(a) to Korean Patent Application No. 10-2024-0097045, filed on Jul. 23, 2024, the entire disclosure of which is incorporated herein by reference.

### TECHNICAL FIELD

One or more embodiments of the present disclosure described herein relate to a semiconductor device, and more particularly, to a semiconductor device including multi-purpose transceiver and an operation method thereof.

### BACKGROUND

A semiconductor device such as a memory device, a controller, and a central processing unit (CPU) has been developed to input and output data or signals at a high speed. In addition, the integration degree for the semiconductor device is increasing. In order to input and output data or signals at a high speed, the number of pins or pads for inputting and outputting the data or signals in the semiconductor device may increase. However, the number of pins or pads may be adjusted or the arrangement for the pins or pads may be designed to avoid, reduce or suppress interference, noise, etc. that may cause an error or malfunction in a limited size or area of the semiconductor device.

### BRIEF DESCRIPTION OF THE DRAWINGS

The description herein makes reference to the accompanying drawings wherein like reference numerals refer to like parts throughout the figures.

FIGS. 1A and 1B illustrate a memory device or a memory system according to an embodiment of the present disclosure.

FIG. 2 illustrates a semiconductor device according to an embodiment of the present disclosure.

FIG. 3 illustrates a memory chip according to an embodiment of the present disclosure.

FIG. 4 illustrates a structure of a transceiver included in a semiconductor device according to an embodiment of the present disclosure.

FIG. 5 illustrates a first operation of the memory device according to an embodiment of the present disclosure.

FIG. 6 illustrates a second operation of the memory device according to an embodiment of the present disclosure.

FIG. 7 illustrates a third operation of the memory device according to an embodiment of the present disclosure.

### DETAILED DESCRIPTION

Various embodiments of the present disclosure are described below with reference to the accompanying drawings. Elements and features of this disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational, e.g., is not turned on nor activated. Examples of block/unit/circuit/component used with the “configured to” language include hardware, circuits, memory storing program instructions executable to implement the operation, etc. Additionally, “configured to” can include a generic structure, e.g., generic circuitry, that is manipulated by software and/or firmware, e.g., an FPGA or a general-purpose processor executing software to operate in a manner that is capable of performing the task(s) at issue. “Configured to” may also include adapting a manufacturing process, e.g., a semiconductor fabrication facility, to fabricate devices, e.g., integrated circuits that are adapted to implement or perform one or more tasks.

As used in this disclosure, the term ‘machine,’ ‘circuitry’ or ‘logic’ refers to all of the following: (a) hardware-only circuit implementations such as implementations in only analog and/or digital circuitry and (b) combinations of circuits and software and/or firmware, such as (as applicable): (i) to a combination of processor(s) or (ii) to portions of processor(s)/software including digital signal processor(s), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘machine,’ ‘circuitry’ or ‘logic’ applies to all uses of this term in this application, including in any claims. As a further example, as used in this application, the term ‘machine,’ ‘circuitry’ or ‘logic’ also covers an implementation of merely a processor or multiple processors or a portion of a processor and its (or their) accompanying software and/or firmware. The term ‘machine,’ ‘circuitry’ or ‘logic’ also covers, for example, and if applicable to a particular claim element, an integrated circuit for a storage device.

As used herein, the terms ‘first,’ ‘second,’ ‘third,’ and so on are used as labels for nouns that they precede, and do not imply any type of ordering, e.g., spatial, temporal, logical, etc. The terms ‘first’ and ‘second’ do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term ‘based on’ is used to describe one or more factors that affect a determination. This term does not foreclose additional factors that may affect determination. The determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

An embodiment of the present disclosure can provide a semiconductor device including a transceiver and an internal circuit, and a method for operating the semiconductor device. The transceiver has a structure with a multipurpose input or output (input/output) pin, pad, port or terminal. The internal circuit is connected to the multipurpose input/output pin/pad, which is designed and capable of changing the usage through an internal control logic or circuit.

In addition, an embodiment of the present disclosure can provide an apparatus and method capable of externally observing the performance of a transceiver in an operational condition or situation. In the operational condition or situation, it is difficult to check an amount of AC characteristic improvement for changing an equalizer coefficient in a semiconductor device which is designed and capable of transmitting and receiving data or signals at a high speed.

In addition, an embodiment of the present disclosure can provide an apparatus and method capable of doubling the performance (e.g., throughput) of a read operation depending on the usage of the multipurpose pin or pad embedded and designed without increasing a width (or an area) of one side of a memory device. Further, an external device coupling to the memory device can directly verify characteristics of communication lines or paths (or signal reception) of the memory device without signal processing performed by an internal circuit of the memory device.

An embodiment of the present disclosure can provide a semiconductor device, including plural electrical terminals or pads; and plural transceivers configured to transmit or receive power, data, or control signals through the plural electrical terminals or pads, and including a first transceiver. The first transceiver is configured to perform an operation based on an operation mode by using a pair of electrical terminals or pads or a single electrical terminal or pad, among the pair of electrical terminals or pads.

The semiconductor device can further include plural memory cells configured to store the data. The pair of electrical terminals or pads can be designated for inputting and outputting the data.

The operation mode can include a first operation mode for outputting the data through the pair of electrical terminals or pads; and a second operation mode for receiving the data through a first electrical terminal or pad among the pair of electrical terminals or pads and transmitting the data through a second electrical terminal or pad among the pair of electrical terminals or pads.

The operation mode can further include a third operation mode for outputting the data through the single electrical terminal or pad; and a fourth operation mode for receiving the data through the single electrical terminal or pad.

The semiconductor device can further include a first receiver configured to receive the data or the control signals; a first transmitter configured to transmit the data or the control signals; and a second transmitter configured to transmit the data or the control signals. The pair of electrical terminals or pads can include a first electrical terminal or pad coupled to the first receiver and the first transmitter; and a second pin or pad electrical terminals or pads coupled to the second transmitter.

The second electrical terminal or pad cannot be capable of receiving the data or the control signals.

The first transceiver can include a multiplexer configured to select one of output data and a loopback signal received by the first receiver. An output of the multiplexer can be delivered to the second transmitter.

The semiconductor device can further include a control device configured to determine whether what is received through the first electrical terminal or pad is input data or the loopback signal; control selection of the multiplexer; and determine whether the second transmitter operates.

The plural electrical terminals or pads can include 8 pairs, 16 pairs, or 32 pairs of data input and output electrical terminals or pads.

In another embodiment, a memory device can include plural memory cells configured to store data; plural electrical terminals or pads configured to input or output the data; and plural transceivers configured to transmit or receive the data through the plural electrical terminals or pads, and including a first transceiver. The first transceiver is configured to perform an operation based on an operation mode by using a pair of electrical terminals or pads or a single electrical terminal or pad, among the pair of electrical terminals or pads.

The operation mode can include a first operation mode for outputting the data through the pair of electrical terminals or pads; and a second operation mode for receiving the data through a first electrical terminal or pad among the pair of electrical terminals or pads and transmitting the data through a second electrical terminal or pad among the pair of electrical terminals or pads.

The operation mode can further include a third operation mode for outputting the data through the single electrical terminal or pad; and a fourth operation mode for receiving the data through the single electrical terminal or pad.

The memory device can further include a first receiver configured to receive the data or signals, a first transmitter configured to transmit the data or the signals, and a second transmitter configured to transmit the data or the signals. The pair of electrical terminals or pads can include a first electrical terminal or pad coupled to the first receiver and the first transmitter; and a second electrical terminal or pad coupled to the second transmitter.

The second electrical terminal or pad cannot be capable of receiving the data or the signals.

The first transceiver can include a multiplexer configured to select one of output data and a loopback signal received by the first receiver. An output of the multiplexer can be delivered to the second transmitter.

The semiconductor device can further include a control device configured to determine whether what is received through the first electrical terminal or pad is input data or the loopback signal; control selection of the multiplexer; and determine whether the second transmitter operates.

The plural electrical terminals or pads can include 8 pairs or 16 pairs of data input and output electrical terminals or pads.

In another embodiment, a method for operating a semiconductor device can include performing, based on a control signal input from an external device, one of: receiving a loop-back signal through a first electrical terminal or pad of a pair of electrical terminals or pads among plural electrical terminals or pads to outputting the loop-back signal through a second electrical terminal or pad of the pair of electrical terminals or pads; and outputting data through the pair of electrical terminals or pads.

The method can further include receiving or outputting the data through one electrical terminal or pad among the pair of electrical terminals or pads.

The second electrical terminal or pad can be inactive when the data is received or output through the second electrical terminal.

These and other features and advantages of the invention will become apparent from the detailed description and the accompanying drawings of embodiments of the present disclosure. Embodiments will now be described with reference to the accompanying drawings, wherein like numbers reference like elements.

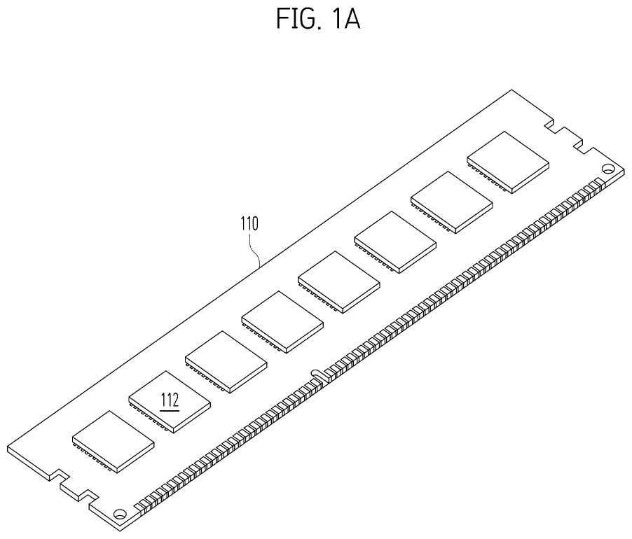

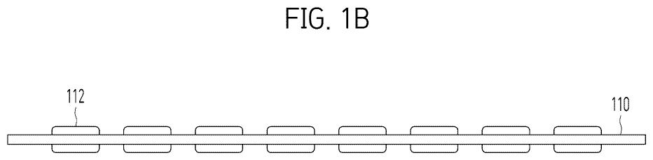

FIGS. 1A and 1B illustrate a memory device or a memory system 100 according to an embodiment of the present disclosure.

Referring to FIGS. 1A and 1B, the memory device or memory system (hereinafter referred to as “memory device”) 110 can have a structure in which a plurality of semiconductor devices 112 are attached onto a printed circuit board (PCB). The plurality of semiconductor devices 112 can be attached to both sides (i.e., top and bottom surfaces) of the printed circuit board. The number of semiconductor devices 112 can vary depending on performance of the memory device 110.

According to an embodiment, the semiconductor device 112 can include a plurality of memory cells capable of storing data. The memory cells can include volatile memory cells, non-volatile memory cells, or a combination of the volatile memory cells and the non-volatile memory cells.

According to an embodiment, the semiconductor device 112 can include a peripheral circuit for storing data in the memory cells and outputting the data from the memory cells. The peripheral circuit can include a control unit which performs at least one of an operation for maintaining data stored in the plurality of memory cells, an operation for storing the data in the plurality of memory cells, an operation for reading the data stored in the plurality of memory cells, and an operation for erasing or deleting the data stored in the plurality of memory cells. The configuration of the control unit can vary depending on operating characteristics of the plurality of memory cells. According to an embodiment, one of the plurality of semiconductor device 112 can include a controller which selectively applies a control signal to other semiconductor devices, selectively transmits data to the other semiconductor devices, or outputs data transmitted from the other semiconductor devices to an external device. For example, the controller can selectively route or provide clocks, commands, addresses, data, etc. to the other semiconductor devices included in the memory device 110.

According to an embodiment, the plurality of semiconductor devices 112 can perform data communication with an external device coupled to the memory device 110, or perform data communication between the plurality of semiconductor devices 122 within the memory device 110. The data communication can include an operation of transmitting and receiving at least one of a control signal, a command, an address, data, and etc.

Although FIGS. 1A and 1B illustrate an embodiment in which the memory device 110 is attached to the printed circuit board (PCB), in another embodiment the memory device 110 can also include a plurality of semiconductor devices that are vertically aligned and coupled.

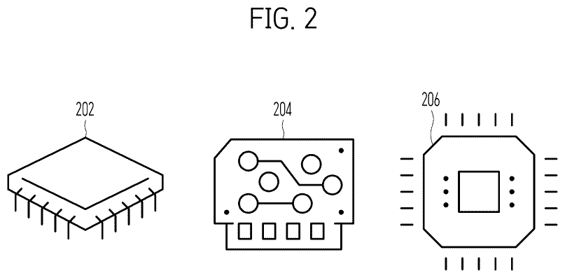

FIG. 2 illustrates a semiconductor device according to an embodiment of the present disclosure.

Referring to FIG. 2, the semiconductor device can have various shapes or structures according to embodiments. In one embodiment, a first semiconductor device 202 can have a hexahedral shape which includes pins, ports, terminals, or pads connected to the outside on at least four sides.

According to an embodiment, a second semiconductor device 204 can include pins or terminals which are coupled to a plurality of components through wires engraved on a printed circuit board. The pins or the terminals of the second semiconductor device 204 can attach to, or detach from, an external device. According to an embodiment, the plurality of components can include ports or pads which are coupled to another component included in the second semiconductor device 204.

According to an embodiment, a third semiconductor device 206 can have a hexahedral shape which can include not only pins or terminals connected to the outside on four sides but also other pins or terminals connected to the outside on a bottom surface.

The first to third semiconductor devices 202, 204, 206 can include a plurality of pins, terminals, ports, or pads for transmitting and receiving power, data, control signals, or the like. At least some of the plurality of pins, terminals, ports, or pads can be designed to be used for multiple purposes. According to an embodiment, the pin or the terminal can include an endpoint for the connection of a package to the external device or the outside. Further, the port or the pad can include a contact for the connection between internal components in the package or the connection of the package to the external device or the outside.

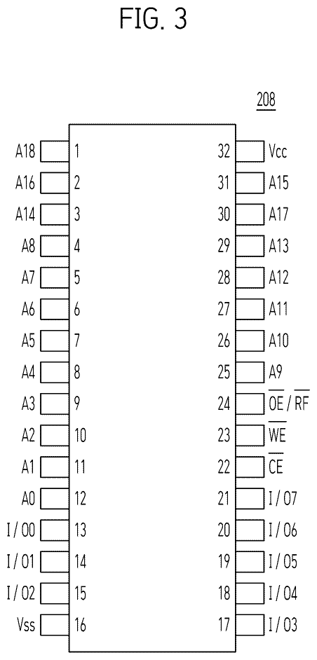

FIG. 3 illustrates a memory chip 208 according to an embodiment of the present disclosure.

Referring to FIG. 3, the memory chip 208 can include a plurality of pins or pads. The memory chip 208 can be understood as an embodiment of the semiconductor device 112 in FIG. 1 or embodiments of the first to third semiconductor devices 202, 204, 206 in FIG. 2. The memory chip 208 can include 32 pins or pads with numbers ‘1’ to ‘32’. The number of pins or pads included in the memory chip 208 can vary depending on an embodiment.

The plurality of pins or pads of the memory chip 208 can include a plurality of address pins or pads AO to A18 to which addresses are input from an external device. The plurality of address pins or pads A0 to A18 are coupled to different address lines. Because the number of the plurality of address pins or pads A0 to A18 are 19, the memory chip 208 can distinguish and receive as many as 2\hat{ }19 (=2¹⁹) addresses. According to an embodiment, the number of the plurality of address pins or pads A0 to A18 can be determined based on data storage capacity which is determined, calculated or estimated by how many of the memory cells are included in the memory chip 208.

The plurality of pins or pads of the memory chip 208 can include a plurality of data pins or pads I/O0 to I/O7 through which data is input from and output to the external device. The data lines coupled to the plurality of data pins or pads I/O0 to I/O7 can transmit data in both directions (i.e., from the memory chip 208 to the external device, and vice versa). When there are eight data lines, eight bits (i.e., one byte) of data can be transmitted simultaneously. According to an embodiment, the number of the plurality of data pins or pads I/O0 to I/O7 can vary. When the number of data lines or the plurality of data pins or pads is 16, 16 bits (i.e., 2 bytes) of data can be transmitted simultaneously between the memory chip 208 and the external device. When the number of data lines or the plurality of data pins or pads is 32, 32 bits (i.e., 4 bytes) of data can be transmitted simultaneously.

The plurality of pins or pads of the memory chip 208 can include plural set-up pins or pads to which control signals, power, etc. are transmitted or applied. For example, power pins or pads Vcc, Vss can be coupled to a power voltage Vcc and a ground voltage Vss. In FIG. 3, there is only one pin or pad coupled to the power voltage Vcc and one pin or pad coupled to the ground voltage Vss. According to an embodiment, the memory chip 208 can include multiple power pins or pads coupled to the power voltage Vss and multiple power pins or pads coupled to the ground voltage Vss. In addition, when multiple power pins or pads are arranged at preset intervals on the outside of the memory chip 208, the power supplied to the inside of the memory chip 208 can be used more efficiently inside the memory chip 208.

According to an embodiment, the plurality of set-up pins or pads can include a chip select or chip enable (CE) signal (/CE) pin or pad for activating the memory chip 208 and an output enable signal (/OE) pin or pad for activating an output of the memory chip 208. In addition, the plurality of set-up pins or pads can include a write enable signal (/WE) pin or pad for activating writing (Write Enable). The output enable signal (/OE) pin or pad can be used for a read operation, and the write enable signal (/WE) pin or pad can be used for a write operation. For example, when an output enable signal (/OE) that is input through the output enable signal (/OE) pin or pad is activated, the memory chip 208 can perform a read operation. At this time, the write enable signal (/WE) can be deactivated. When the write enable signal (/WE) that is input through a write enable signal (/WE) pin or pad is activated, the memory chip 208 can perform a write operation. At this time, the output enable signal (/OE) may be deactivated.

For example, a write operation performed by the memory chip 208 can be sequentially controlled through multiple pins or pads. First, the chip select signal (/CE) can be activated (e.g., a logic low level). Then, the write enable signal (/WE) can be activated. Next, the memory chip 208 can receive an address at which data is to be written through the plurality of address pins or pads A0 to A18. Then, the memory chip 208 can receive data transmitted through the plurality of data pins or pads I/O0 to I/O7. After the write operation is completed, the chip select signal (/CE) can be deactivated (e.g., a logic high level).

A read operation performed by the memory chip 208 may be sequentially controlled through multiple pins or pads. First, the chip select signal (/CE) can be activated (e.g., the logic low level). Then, the output enable signal (/OE) can be activated. Next, the memory chip 208 can receive an address indicating a location of data through the plurality of address pins or pads A0 to A18. Then, the memory chip 208 can read data stored in the location corresponding to the input address, and then output the read data through the plurality of data pins or pads I/O0 to I/O7. After the read operation is completed, the chip select signal (/CE) can be deactivated (e.g., the logic high level).

Arrangements (e.g., locations) for the plurality of address pins or pads A0 to A18, the plurality of data pins or pads I/O0 to I/O7, and the plurality of set-up pins or pads among the plurality of pins or pads included in the memory chip 208 can vary depending on an embodiment. Some of the plurality of pins or pads can be used for receiving data or signals, while others are used for transmitting and receiving data or signals. As the integration of the memory chip 208 increases, physical locations for a reception path and a transmission path of data or signals in the memory chip 208 can vary due to several reasons such as electromagnetic interference (EMI), optimization of the data or signal paths, and optimization of the layout and arrangement of internal components.

Referring to FIGS. 1 to 3, the semiconductor device 112, the first to third semiconductor devices 202, 204, 206, and the memory chip 208 can be designed to transmit and receive addresses, data, signals, etc. at high speed. When the semiconductor device 112, the first to third semiconductor devices 202, 204, 206, and the memory chip 208 are required to operate at high speed even in a low-power environment, operation margin(s) for transmitting and receiving addresses, data, signals, etc. might not be sufficiently great. In addition, an operating environment (e.g., temperature, resistance, etc.) of the semiconductor device 112, the first to third semiconductor devices 202, 204, 206, and the memory chip 208 can change in real time. Thus, it might be necessary to reduce or avoid an error occurring in high-speed data communication.

For high-speed data communication, a control device (or an external device) operatively engaged with the semiconductor device 112, the first to third semiconductor devices 202, 204, 206, and the memory chip 208 can use, or include, an equalizer. The equalizer can compensate for channel distortion or improve signal quality. For example, the equalizer can compensate for a phenomenon in which high-frequency components are more attenuated in order to compensate for frequency-dependent channel distortion occurring in the data transmission process. In addition, the equalizer can improve an eye pattern of a received signal and reduce a bit error rate (BER) by compensating for channel distortion. As the operating environment of the semiconductor device 112, the first to third semiconductor devices 202, 204, 206, and the memory chip 208 changes, the equalizer can adaptively adjust an equalizer coefficient in real time to respond to the situation of the signal or data line (e.g., channel).

In order to adaptively adjust the equalizer coefficient, it can be necessary to perform a debugging operation for transmission and reception of the signal or data between two devices or chips. In order to accurately adjust the equalizer coefficient for the transceiver in the semiconductor device 112, the first to third semiconductor devices 202, 204, 206, and the memory chip 208 operating at high speed, it can be necessary to perform a debugging operation for closely checking the AC characteristic improvement amount over an entire range. However, it can be very difficult to perform this debugging operation in real time during operations of the semiconductor device 112, the first to third semiconductor devices 202, 204, 206, and the memory chip 208. Thus, the semiconductor device 112, the first to third semiconductor devices 202, 204, 206, and the memory chip 208 can operate in a loopback operation mode to adaptively adjust the equalizer coefficient in a simple and quick method.

In the loopback operation mode, an external device connected to the semiconductor device 112, the first to third semiconductor devices 202, 204, 206, or the memory chip 208 can receive a signal transmitted from itself to the semiconductor device 112, the first to third semiconductor devices 202, 204, 206, or the memory chip 208. At this time, in the semiconductor device 112, the first to third semiconductor devices 202, 204, 206, or the memory chip 208, a receiver can be internally coupled to a transmitter. Through this, the external device can check an operation status, performance, etc. of the transmission and reception paths of the semiconductor device 112, the first to third semiconductor devices 202, 204, 206, and the memory chip 208. Further, the external device can adaptively adjust an equalizer coefficient. According to an embodiment, the loopback operation mode can be performed on at least some of the plurality of pins or pads in the semiconductor device 112, the first to third semiconductor devices 202, 204, 206, or the memory chip 208.

According to an embodiment, the semiconductor device 112, the first to third semiconductor devices 202, 204, 206, or the memory chip 208 can change the number of receivers and transmitters that operate depending on an operation mode. After fabrication, it can be impossible to physically add or remove some receivers and transmitters included in the semiconductor device 112, the first to third semiconductor devices 202, 204, 206, or the memory chip 208. However, some of the receivers and transmitters included in the semiconductor device 112, the first to third semiconductor devices 202, 204, 206, or the memory chip 208 can be selectively activated or deactivated depending on the operation mode. Through this scheme, the input/output performance of signals and data of the semiconductor device 112, the first to third semiconductor devices 202, 204, 206, or the memory chip 208 can be changed or adjusted, so that power efficiency of the semiconductor device 112, the first to third semiconductor devices 202, 204, 206, or the memory chip 208 could be improved. In addition, the performance of the semiconductor device 112, the first to third semiconductor devices 202, 204, 206, or the memory chip 208 can be flexibly adjusted depending on the performance of a system including the semiconductor device 112, the first to third semiconductor devices 202, 204, 206, or the memory chip 208.

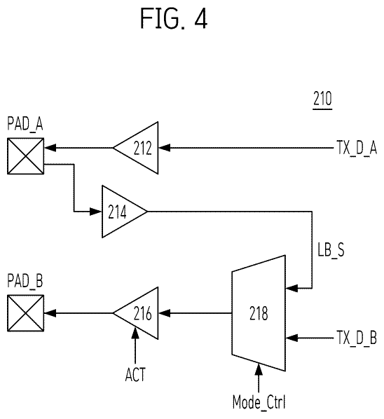

FIG. 4 illustrates a structure of a transceiver 210 included in a semiconductor device according to an embodiment of the present disclosure.

Referring to FIG. 4, the transceiver 210 may include a pair of pins or pads PAD_A, PAD_B. Depending on an embodiment, the pair of pins or pads PAD_A, PAD_B can be a part of the plurality of pins or pads included in the memory chip 208 described in FIG. 3. For example, the pair of pins or pads PAD_A, PAD_B can be a part of the plurality of data pins or pads I/O0 to I/O7 described in FIG. 3.

The pair of pins or pads PAD_A, PAD_B can include a first pin or pad PAD_A which is coupled to both a first receiver 214 configured to receive data or control signals and a first transmitter 212 configured to output data or control signals. The pair of pins or pads PAD_A, PAD_B can include a second pin or pad PAD_B coupled to a second transmitter 216 configured to output data or control signals. Depending on an embodiment, the second pin or pad PAD_B could not be capable of receiving any data or control signals.

Depending on an operation mode, the transceiver 210 can use the pair of pins or pads PAD_A, PAD_B or only one of the pair of pins or pads PAD_A, PAD_B. For example, in the first operation mode, data TX_D_A, TX_D_B can be output through the pair of pins or pads PAD_A, PAD_B. When the semiconductor device includes 8 pairs of data input/output pins or pads, the semiconductor device can output 16 bits (i.e., two bytes) of data simultaneously in the first operation mode. When the semiconductor device includes 16 pairs of data input/output pins or pads, the semiconductor device can output 32 bits (i.e., four bytes) of data simultaneously in the first operation mode.

In the second operation mode, the transceiver 210 can receive a loopback signal LB_S transmitted from an external device through the first pin or pad PAD_A of the pair of pins or pads PAD_A, PAD_B, and then output the received loopback signal LB_S to the external device through the second pin or pad PAD_B. When the semiconductor device includes eight pairs of pins or pads, the semiconductor device can receive an 8-bit loopback signal LB_S through eight pins or pads out of the eight pairs of pins or pads (i.e., 16 pins or pads) in the second operation mode, and then output the 8-bit loopback signal LB_S to the external device through the other eight pins or pads. For the second operation mode, the transceiver 210 can include a multiplexer 218. The multiplexer 218 can select one loopback signal LB_S received through the first receiver 214 and output data TX_D_B in response to a mode control signal Mode_Ctrl. The output of the multiplexer 218 can be delivered to the second transmitter 216.

In the third operation mode, the transceiver 210 can output the data TX_D_A only through the first pin or pad PAD_A among the pair of pins or pads PAD_A, PAD_B. At this time, the second transmitter 216 coupled to the second pin or pad PAD_B can be deactivated in response to an activation signal ACT. In the third operation mode, the size of data simultaneously output in the first operation mode can be reduced to half, but power consumption of the transceiver 210 could be also reduced by deactivating the second transmitter 216 coupled to the second pin or pad PAD_B. For example, when the semiconductor device includes 8 pairs of data input/output pins or pads, the semiconductor device can simultaneously output 8 bits (i.e., one byte) of data in the third operation mode. When the semiconductor device includes 16 pairs of data input/output pins or pads, the semiconductor device can simultaneously output 16 bits (i.e., two bytes) of data in the third operation mode.

In the fourth operation mode, the transceiver 210 can receive data only through the first pin or pad PAD_A among the pair of pins or pads PAD_A, PAD_B. The data received through the first pin or pad PAD_A can be transmitted to internal components of the semiconductor device coupled to the transceiver 210 through the first receiver 214. The data received in the fourth operation mode can be distinguished from the loopback signal LB_S received in the second operation mode. For example, when the transceiver 210 is included in the memory device, the data received in the fourth operation mode can be write data to be stored in the memory device. The loopback signal LB_S received in the second operation mode can be a signal used for a debugging operation. Because the second pin or pad PAD_B might not be used in the fourth operation mode, the second transmitter 216 can be deactivated in response to the activation signal ACT. For example, when the semiconductor device includes 8 pairs of data input/output pins or pads, the semiconductor device can receive 8 bits (i.e., one byte) of data simultaneously in the fourth operation mode. When the semiconductor device includes 16 pairs of data input/output pins or pads, the semiconductor device can receive 16 bits (i.e., two bytes) of data simultaneously in the fourth operation mode.

The first operation mode to the fourth operation mode can be selected according to a preset communication protocol between a semiconductor device including the transceiver 210 and an external device (e.g., a controller or a host) that is coupled to the semiconductor device. Through the transceiver 210 coupled to multipurpose pins or pads, the semiconductor device can adjust data output performance, perform real-time debugging operation, and provide data reception.

According to an embodiment, the transceiver 210 can be applied to pins or pads (e.g., set-up pins or pads) designated to be used for a purpose other than pins or pads designated for data input/output among the plurality of pins or pads included in the semiconductor device.

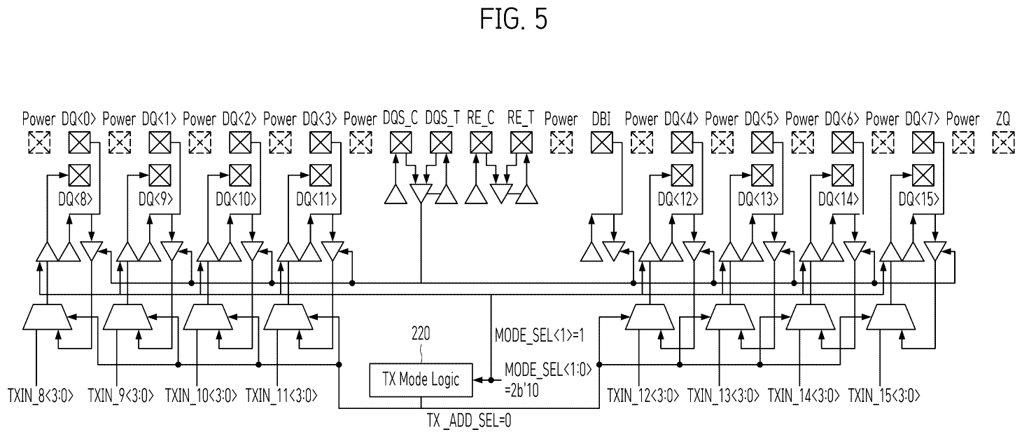

Hereinafter, with reference to FIGS. 5 to 7, in an embodiment showing a memory device including 8 pairs of data input/output pins or pads (i.e., 16 data input/output pins or pads, DQ<0:15>), an apparatus and a method for controlling 8 pairs of data input/output pins or pads based on plural operation modes will be described. Specifically, the configuration of a circuit coupled to each pair of the 8 pairs of data input/output pins or pads can be substantially the same as the transceiver 210 described in FIG. 4. The memory device can include a transceiver (TX) mode logic 220 configured to determine an operation mode of the transceiver 210 and transmit at least one control signal to the transceiver 210.

With reference to FIGS. 4 to 7, the transceiver mode logic 220 may output a first control signal TX_ADD_SEL and a second control signal MODE_SEL<1>to each transceiver. The first control signal TX_ADD_SEL can correspond to the mode control signal Mode_Ctrl in FIG. 4, while the second control signal MODE_SEL<1>can correspond to the activation signal ACT in FIG. 4.

FIG. 5 illustrates a first operation of the memory device according to an embodiment of the present disclosure. The first operation can correspond to the first operation mode described in FIG. 4.

Referring to FIG. 5, in order to perform the first operation, a control circuit in the memory device can transmit the mode selection code MODE_SEL<1:0>of ‘2b′10’ to the transceiver mode logic 220. In response to the mode selection code (MODE_SEL<1:0>=2b′10), the transceiver mode logic 220 can output the first control signal TX_ADD_SEL of the logic low level (‘0’) and output the second control signal MODE_SEL<1>of the logic high level (‘1’). In response to the first control signal TX_ADD_SEL of the logic low level (‘0’) (i.e., TX_ADD_SEL=0), the multiplexer 218 in FIG. 4 included in the transceiver can select data TXIN_8<3:0>to TXIN_15<3:0>output to an external device instead of the loopback signal LB_S. In addition, the transmitter 216 in FIG. 4 coupled to eight data input/output pins or pads DQ<8:15>can be activated based on the second control signal MODE_SEL<1>of the logic high level (‘1’) (i.e., MODE_SEL<1>=1). Therefore, through eight pairs of data input/output pins or pads (i.e., 16 data input/output pins or pads DQ<0:15>), the transceiver mode logic 220 can control the transceiver 210 to output 16 bits (i.e., two bytes) of data simultaneously.

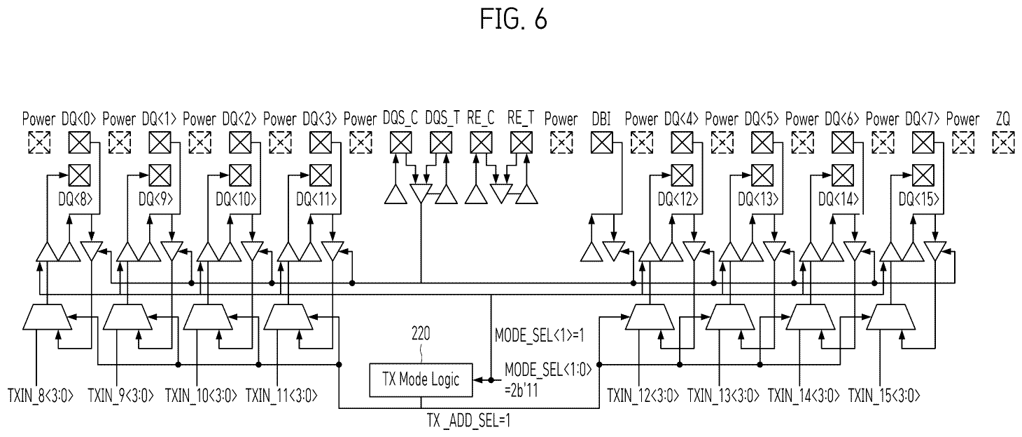

FIG. 6 illustrates a second operation of the memory device according to an embodiment of the present disclosure. The second operation can correspond to the second operation mode described in FIG. 4.

Referring to FIG. 6, in order to perform the second operation, a control circuit within the memory device can transmit the mode selection code MODE_SEL<1:0>of ‘2b′11’ to the transceiver mode logic 220. In response to the mode selection code (MODE_SEL<1:0>=2b′11), the transceiver mode logic 220 may output the first control signal TX_ADD_SEL of the logic high level (‘1’) and output the second control signal MODE_SEL<1>of the logic high level (‘1’). In response to the first control signal TX_ADD_SEL of a logic low level (‘1’) (i.e., TX_ADD_SEL=1), the multiplexer 218 in FIG. 4 can select a loopback signal LB_S input through the receiver 214 in FIG. 4 coupled to eight data input/output pins or pads DQ<0:7>rather than data TXIN_8<3:0>to TXIN_15<3:0>output to an external device. In addition, the transmitter 216 in FIG. 4 coupled to eight data input/output pins or pads DQ<8:15>can be activated based on the second control signal MODE_SEL<1>of the logic high level (‘1’) (i.e., MODE_SEL<1>=1). Accordingly, an 8-bit loopback signal LB_S input from the external device through 8 data input/output pins or pads DQ<0:7>among 8 pairs of data input/output pins or pads can be output to the external device through the other 8 data input/output pins or pads DQ<8:15>. Through this operation, the transceiver mode logic 220 can control the transceiver 210 to perform a loop-back mode for a debugging operation.

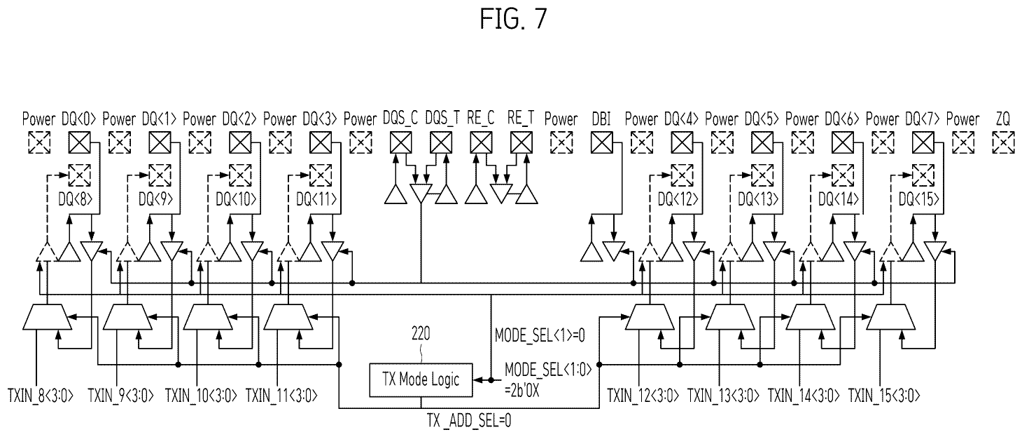

FIG. 7 illustrates a third operation of the memory device according to an embodiment of the present disclosure. The third operation can correspond to the third operation mode described in FIG. 4.

Referring to FIG. 7, in order to perform the third operation, a control circuit in the memory device can transmit the mode selection code (MODE_SEL<1:0>) of ‘2b′0X’ to the transceiver mode logic 220. In response to the mode selection code (MODE_SEL<1:0>=2b′1X), the transceiver mode logic 220 may output a first control signal TX_ADD_SEL of the logic low level (‘0’) and output a second control signal MODE_SEL<1>of the logic low level (‘0’). In response to the first control signal TX_ADD_SEL of the logic low level (‘0’) (i.e., TX_ADD_SEL=0), the multiplexer 218 in FIG. 4 can select data TXIN_8<3:0>to TXIN_15<3:0>to be output to the external device rather than the loopback signal LB_S. However, the transmitter 216 in FIG. 4 coupled to eight data input/output pins or pads DQ<8:15>could be deactivated based on the second control signal MODE_SEL<1>of the logic low level (‘0’) (i.e., MODE_SEL<1>=0). Therefore, the transceiver mode logic 220 can control the transceiver 210 to simultaneously output 8 bits of data through 8 data input/output pins or pads DQ<0:7>among 8 pairs of data input/output pins or pads (i.e., 16 data input/output pins or pads DQ<0:15>). Data might not be output through the other 8 data input/output pins or pads DQ<8:15>.

As described above, a semiconductor device, a memory device, or a memory chip according to an embodiment of the present disclosure can include plural pins or pads for inputting/outputting data, plural pins or pads for transmitting addresses indicating a location of data, and plural set-up pins or pads for setting an operation performed within the semiconductor device, the memory device, or the memory chip. According to an embodiment, with reference to FIGS. 5 to 7, a semiconductor device, a memory device, or a memory chip can include pins or pads for transmitting or receiving a data strobe signal DQS_T and a data strobe complement signal DQS_C, pins or pads for a data master or data bus inversion DBI, pins or pads for a read enable signal RE_T and a read enable complement signal RE_C, and the like. According to an embodiment of the present disclosure, through at least one pair among a plurality of pins or pads included in a semiconductor device, a memory device, or a memory chip, various operation modes can be selectively performed by a transceiver mode logic based at least on operating characteristics or conditions.

As above described, a semiconductor device according to an embodiment of the present disclosure can use at least one pin or pad for multiple purposes, so that it is easier to secure a design margin for arranging pins or pads in the semiconductor device than a conventional semiconductor device without no multipurpose pin/pad.

In addition, a memory device or a memory system according to an embodiment of the present disclosure can adjust the performance of a read operation or perform a compensation operation to reduce or avoid an error in the transmission of data or signals, depending on an operation mode.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods or operations of the computer, processor, controller, or other signal processing device, are described in detail, the code or instructions for implementing the operations of the method embodiments may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, generators, logic, interfaces, decoders, drivers, and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, generators, logic, interfaces, decoders, drivers, and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, generators, logic, interfaces, decoders, drivers, and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods or operations of the computer, processor, microprocessor, controller, or other signal processing device, are described in detail, the code or instructions for implementing the operations of the method embodiments may transform the computer, processor, controller, or other signal processing device into a special-purpose processor for performing the methods described herein.

While the embodiments of the present disclosure have been illustrated and described with respect to specific embodiments, it will be apparent to those skilled in the art in light of the present disclosure that various changes and modifications may be made without departing from the spirit and scope of the disclosure as defined in the following claims. Furthermore, the embodiments may be combined to form additional embodiments.

What is claimed is:

1. A semiconductor device comprising:
plural electrical terminals or pads; and
plural transceivers configured to transmit or receive power, data, or control signals through the plural electrical terminals or pads, and including a first transceiver,
wherein the first transceiver is configured to perform an operation based on an operation mode by using a pair of electrical terminals or pads or a single electrical terminal or pad, among the pair of electrical terminals or pads.

2. The semiconductor device according to claim 1, further comprising plural memory cells configured to store the data, and
wherein the pair of electrical terminals or pads is designated for inputting and outputting the data.

3. The semiconductor device according to claim 2, wherein the operation mode comprises:
a first operation mode for outputting the data through the pair of electrical terminals or pads; and
a second operation mode for receiving the data through a first electrical terminal or pad among the pair of electrical terminals or pads and transmitting the data through a second electrical terminal or pad among the pair of electrical terminals or pads.

4. The semiconductor device according to claim 2, wherein the operation mode comprises:
a third operation mode for outputting the data through the single electrical terminal or pad; and
a fourth operation mode for receiving the data through the single electrical terminal or pad.

5. The semiconductor device according to claim 1, further comprising:
a first receiver configured to receive the data or the control signals;
a first transmitter configured to transmit the data or the control signals; and
a second transmitter configured to transmit the data or the control signals,
wherein the pair of electrical terminals or pads comprises:
a first electrical terminal or pad coupled to the first receiver and the first transmitter; and
a second electrical terminal or pad coupled to the second transmitter.

6. The semiconductor device according to claim 5, wherein the second electrical terminal or pad is not capable of receiving the data or the control signals.

7. The semiconductor device according to claim 5, wherein the first transceiver comprises a multiplexer configured to select one of output data and a loopback signal received by the first receiver, and
wherein an output of the multiplexer is delivered to the second transmitter.

8. The semiconductor device according to claim 7, further comprising a control device configured to:
determine whether what is received through the first electrical terminal or pad is input data or the loopback signal;
control selection of the multiplexer; and
determine whether the second transmitter operates.

9. The semiconductor device according to claim 1, wherein the plural electrical terminals or pads comprise 8 pairs, 16 pairs, or 32 pairs of data input and output electrical terminals or pads.

10. A memory device comprising:
plural memory cells configured to store data;
plural electrical terminals or pads configured to input or output the data; and
plural transceivers configured to transmit or receive the data through the plural electrical terminals or pads, and including a first transceiver,
wherein the first transceiver is configured to perform an operation based on an operation mode by using a pair of electrical terminals or pads or a single electrical terminal or pad, among the pair of electrical terminals or pads.

11. The memory device according to claim 10, wherein the operation mode comprises:
a first operation mode for outputting the data through the pair of electrical terminals or pads; and
a second operation mode for receiving the data through a first electrical terminal or pad among the pair of electrical terminals or pads and transmitting the data through a second electrical terminal or pad among the pair of electrical terminals or pads.

12. The memory device according to claim 10, wherein the operation mode comprises:
a third operation mode for outputting the data through the single electrical terminal or pad; and
a fourth operation mode for receiving the data through the single electrical terminal or pad.

13. The memory device according to claim 10, further comprising:
a first receiver configured to receive the data or signals;
a first transmitter configured to transmit the data or the signals; and
a second transmitter configured to transmit the data or the signals,
wherein the pair of electrical terminals or pads comprises:
a first electrical terminal or pad coupled to the first receiver and the first transmitter; and
a second electrical terminal or pad coupled to the second transmitter.

14. The memory device according to claim 13, wherein the second electrical terminal or pad is not capable of receiving the data or the signals.

15. The memory device according to claim 13, wherein the first transceiver comprises a multiplexer configured to select one of output data and a loopback signal received by the first receiver, and
wherein an output of the multiplexer is delivered to the second transmitter.

16. The memory device according to claim 15, further comprising a control device configured to:
determine whether what is received through the first electrical terminal or pad is input data or the loopback signal;
control selection of the multiplexer; and
determine whether the second transmitter operates.

17. The memory device according to claim 16, the plural electrical terminals or pads comprise 8 pairs or 16 pairs of data input and output electrical terminals or pads.

18. A method for operating a semiconductor device, the method comprising:
performing, based on a control signal input from an external device, one of:
receiving a loop-back signal through a first electrical terminal or pad of a pair of electrical terminals or pads among plural electrical terminals or pads to output the loop-back signal through a second electrical terminal or pad of the pair of electrical terminals or pads; and
outputting data through the pair of electrical terminals or pads.

19. The method according to claim 18, further comprising:
receiving or outputting the data through one electrical terminal or pad among the pair of electrical terminals or pads.

20. The method according to claim 19, wherein the second electrical terminal or pad is inactive when the data is received or output through the first electrical terminal or pad.
